(19) United States
(12) Patent Application Publication
(10) Pub. No.: US 2026/0068493 A1
(43) Pub. Date: Mar. 5, 2026

(54) DISPLAY APPARATUS AND ELECTRONIC APPARATUS INCLUDING THE SAME

(71) Applicant: Samsung Display Co., Ltd., Yongin-si (KR)

(72) Inventors: Jongseok Han, Yongin-si (KR); Dalho Kim, Yongin-si (KR); Jiyoung Kim, Yongin-si (KR); Eunji Park, Yongin-si (KR); Hyangki Sung, Yongin-si (KR); Heeseong Jeong, Yongin-si (KR)

(21) Appl. No.: 19/250,762

(22) Filed: Jun. 26, 2025

(30) Foreign Application Priority Data
Aug. 30, 2024 (KR) 10-2024-0117884

(51) Int. Cl. H10K 59/80

(52) U.S. Cl. CPC H10K 59/873; H10K 59/879

(57) ABSTRACT

A display apparatus includes a display element disposed over a substrate, and an encapsulation layer disposed on the display element and including a first inorganic encapsulation layer, a second inorganic encapsulation layer, and an organic encapsulation layer, where the first inorganic encapsulation layer includes a first-first inorganic encapsulation layer including silicon nitride, a first-second inorganic encapsulation layer disposed over the first-first inorganic encapsulation layer and having a refractive index less than a refractive index of the first-first inorganic encapsulation layer, and a first-third inorganic encapsulation layer disposed between the first-first inorganic encapsulation layer and the first-second inorganic encapsulation layer and having a refractive index less than the refractive index of the first-first inorganic encapsulation layer and greater than the refractive index of the first-second inorganic encapsulation layer. The refractive index of the first-third inorganic encapsulation layer is greater than 1.75 and less than 1.80.

This application claims priority to Korean Patent Application No. 10-2024-0117884, filed on Aug. 30, 2024, and all the benefits accruing therefrom under 35 U.S.C. § 119, the content of which in its entirety is herein incorporated by reference.

### BACKGROUND

### 1. Field

Embodiments relate to a display apparatus and an electronic apparatus including the same, and more particularly, to a display apparatus with improved reliability and improved display quality, and an electronic apparatus including the display apparatus.

### 2. Description of the Related Art

Display apparatuses include an organic light-emitting diode as a display element. An organic light-emitting diode includes a pixel electrode, an opposite electrode, and an emission layer therebetween. Because the organic light-emitting diode may be easily damaged by external moisture, oxygen, or the like, an encapsulation layer protects the organic light-emitting diode by covering the organic light-emitting diode. In addition, the encapsulation layer is disposed on the display element and serves as an optical layer controlling a light extraction efficiency and a viewing angle characteristic of the display element.

### SUMMARY

However, in a display apparatus according to the related art, the reliability of an encapsulation layer is relatively low and images of different color coordinates may be recognized depending on a viewing angle at which the display apparatus is viewed.

Embodiments include a display apparatus with improved reliability and improved display quality and an electronic apparatus including the display apparatus. However, such a technical feature is just an example, and the disclosure is not limited thereto.

Additional features will be set forth in part in the description which follows and, in part, will be apparent from the description, or may be learned by practice of the presented embodiments of the disclosure.

In an embodiment of the disclosure, a display apparatus includes a display element disposed over a substrate, and an encapsulation layer disposed on the display element and including a first inorganic encapsulation layer, a second inorganic encapsulation layer, and an organic encapsulation layer between the first inorganic encapsulation layer and the second inorganic encapsulation layer, where the first inorganic encapsulation layer includes a first-first inorganic encapsulation layer including silicon nitride, a first-second inorganic encapsulation layer disposed over the first-first inorganic encapsulation layer and having a refractive index less than a refractive index of the first-first inorganic encapsulation layer, and a first-third inorganic encapsulation layer disposed between the first-first inorganic encapsulation layer and the first-second inorganic encapsulation layer and having a refractive index less than the refractive index of the first-first inorganic encapsulation layer and greater than the refractive index of the first-second inorganic encapsulation layer, where the refractive index of the first-third inorganic encapsulation layer is greater than 1.75 and less than 1.80.

In an embodiment, the refractive index of the first-first inorganic encapsulation layer may be ranged from about 1.85 to about 2.00, and the refractive index of the first-second inorganic encapsulation layer may be ranged from a refractive index of about 1.52 to about 1.70.

In an embodiment, each of the first-second inorganic encapsulation layer and the first-third inorganic encapsulation layer may include silicon oxynitride, and oxygen content of the first-third inorganic encapsulation layer may be less than oxygen content of the first-second inorganic encapsulation layer.

In an embodiment, nitrogen content of the first-third inorganic encapsulation layer may be greater than nitrogen content of the first-second inorganic encapsulation layer.

In an embodiment, the first-second inorganic encapsulation layer may have a thickness of about 5,200 angstroms (Å) to about 6,200 Å, and the first-third inorganic encapsulation layer may have a thickness of about 2,500 Å to about 3,500 Å.

In an embodiment, the first-first inorganic encapsulation layer may have a thickness of about 1,150 Å to about 1,550 Å.

In an embodiment, the first-third inorganic encapsulation layer may be in direct contact with the first-first inorganic encapsulation layer, and the first-second inorganic encapsulation layer may be in direct contact with the first-third inorganic encapsulation layer.

In an embodiment, the display apparatus may further include a capping layer disposed between the display element and the encapsulation layer, and a buffer layer disposed between the capping layer and the encapsulation layer.

In an embodiment, the capping layer may have a refractive index greater than a refractive index of the buffer layer, and the refractive index of the buffer layer may be less than the refractive index of the first-first inorganic encapsulation layer.

In an embodiment, the refractive index of the capping layer may be ranged from about 1.60 to about 2.30, and the refractive index of the buffer layer may be ranged from about 1.20 to about 1.62.

In an embodiment of the disclosure, an electronic apparatus includes a display apparatus including a display element disposed over a substrate, and an encapsulation layer disposed on the display element and including a first inorganic encapsulation layer, a second inorganic encapsulation layer, and an organic encapsulation layer between the first inorganic encapsulation layer and the second inorganic encapsulation layer, and a housing accommodating the display apparatus and constituting an exterior, where the first inorganic encapsulation layer includes a first-first inorganic encapsulation layer including silicon nitride, a first-second inorganic encapsulation layer disposed over the first-first inorganic encapsulation layer and having a refractive index less than a refractive index of the first-first inorganic encapsulation layer, and a first-third inorganic encapsulation layer disposed between the first-first inorganic encapsulation layer and the first-second inorganic encapsulation layer and having a refractive index less than the refractive index of the first-first inorganic encapsulation layer and greater than the refractive index of the first-second inorganic encapsulation layer, where the refractive index of the first-third inorganic encapsulation layer is greater than 1.75 and less than 1.80.

In an embodiment, the refractive index of the first-first inorganic encapsulation layer may be ranged from about 1.85 to about 2.00, and the refractive index of the first-second inorganic encapsulation layer may be ranged from about 1.52 to about 1.70.

In an embodiment, each of the first-second inorganic encapsulation layer and the first-third inorganic encapsulation layer may include silicon oxynitride, and oxygen content of the first-third inorganic encapsulation layer may be less than oxygen content of the first-second inorganic encapsulation layer.

In an embodiment, nitrogen content of the first-third inorganic encapsulation layer may be greater than nitrogen content of the first-second inorganic encapsulation layer.

In an embodiment, the first-second inorganic encapsulation layer may have a thickness of about 5,200 Å to about 6,200 Å, and the first-third inorganic encapsulation layer may have a thickness of about 2,500 Å to about 3,500 Å.

In an embodiment, the first-first inorganic encapsulation layer may have a thickness of about 1,150 Å to about 1,550 Å.

In an embodiment, the first-third inorganic encapsulation layer may be in direct contact with the first-first inorganic encapsulation layer, and the first-second inorganic encapsulation layer may be in direct contact with the first-third inorganic encapsulation layer.

In an embodiment, the electronic apparatus may further include a capping layer disposed between the display element and the encapsulation layer, and a buffer layer disposed between the capping layer and the encapsulation layer.

In an embodiment, the capping layer may have a refractive index greater than a refractive index of the buffer layer, and the refractive index of the buffer layer may be less than the refractive index of the first-first inorganic encapsulation layer.

In an embodiment, the refractive index of the capping layer may be ranged from about 1.60 to about 2.30, and the refractive index of the buffer layer may be ranged from about 1.20 to about 1.62.

These and/or other features will become apparent and more readily appreciated from the following detailed description, the accompanying drawings, and claims.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a schematic perspective view of an embodiment of an electronic apparatus;

FIG. 2 is a schematic plan view of an embodiment of a display apparatus;

FIG. 3 is an equivalent circuit diagram of a pixel circuit included in the display apparatus of FIG. 2;

FIG. 4 is a schematic cross-sectional view of the display apparatus of FIG. 2, taken along line I-I′ of FIG. 2;

FIGS. 5A to 5J are views to explain an influence of thicknesses of sub-layers of a first inorganic encapsulation layer on color coordinates according to a viewing angle; and

FIG. 6 is a schematic cross-sectional view of an embodiment of a display apparatus.

### DETAILED DESCRIPTION

Reference will now be made in detail to embodiments, illustrative embodiments of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, illustrative embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

While such terms as “first” and “second” may be used to describe various components, such components must not be limited to the above terms. The above terms are used to distinguish one component from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or components but do not preclude the addition of one or more other features or components.

In the specification, “A and/or B” means A or B, or A and B. In the specification, “at least one of A and B”means A or B, or A and B.

In the specification, when various elements such as a layer, a region, a plate, and the like are disposed “on” another element, not only the elements may be disposed “directly on” the other element, but another element may be disposed therebetween.

It will be understood that when a layer, region, or component is referred to as being “connected” to another layer, region, or component, it may be “directly connected” to the other layer, region, or component or may be “indirectly connected” to the other layer, region, or component with other layer, region, or component interposed therebetween. For example, it will be understood that when a layer, region, or element is referred to as being “electrically connected” to another layer, region, or element, it may be “directly electrically connected” to the other layer, region, or element or may be “indirectly electrically connected” to the other layer, region, or element with another layer, region, or element interposed therebetween.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Hereinafter, embodiments will be described with reference to the accompanying drawings, where like reference numerals refer to like elements throughout and a repeated description thereof is omitted. Sizes of elements in the drawings may be exaggerated or reduced for convenience of explanation. In an embodiment, the size and thickness of each element shown in the drawings are arbitrarily represented for convenience of description, and thus, the disclosure is not necessarily limited thereto.

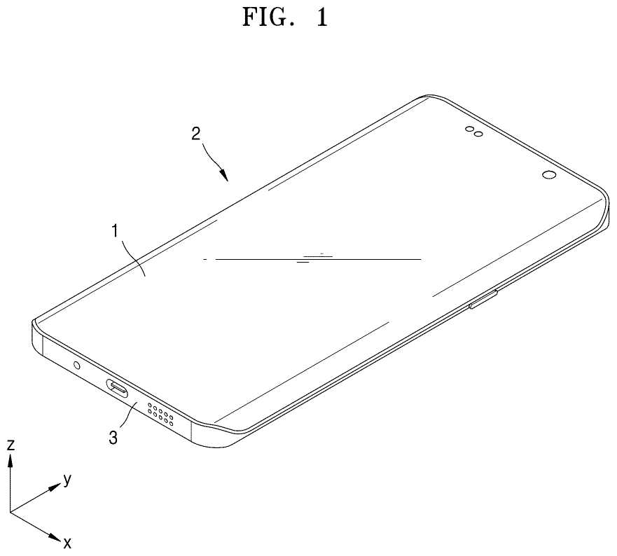

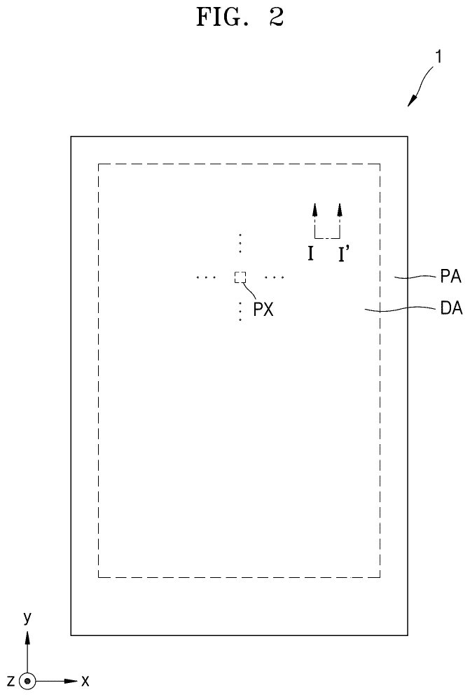

FIG. 1 is a schematic perspective view of an embodiment of an electronic apparatus 2. FIG. 2 is a schematic plan view of an embodiment of a display apparatus 1.

As shown in FIGS. 1 and 2, the display apparatus 1 is an apparatus which displays moving images or still images, and may display a screen or to input or output data in the electronic apparatus 2.

Although it is shown in FIG. 1 that the display apparatus 1 is used in a mobile phone in an embodiment, the disclosure is not limited thereto. In an embodiment, the display apparatus 1 may be used as a display screen in various electronic apparatuses including televisions, notebook computers, monitors, advertisement boards, Internet of things (“IoTs”) apparatuses as well as portable electronic apparatuses including mobile phones, smartphones, tablet personal computers, mobile communication terminals, electronic organizers, electronic books, portable multimedia players (“PMPs”), navigations, and ultra mobile personal computers (“UMPCs”).

In addition, the display apparatus 1 in an embodiment may be used in electronic apparatuses such as wearable devices including smartwatches, watchphones, glasses-type displays, and head-mounted displays (“HMDs”). In an embodiment, the display apparatus 1 is applicable to a display screen in various electronic apparatuses, such as a display screen in instrument panels for automobiles, center fascias for automobiles, or center information displays (“CIDs”) arranged on a dashboard, room mirror displays that replace side mirrors of automobiles, and displays of an entertainment system arranged on the backside of front seats for backseat passengers in automobiles.

In an embodiment, the display apparatus 1 may be accommodated in a housing 3 of the electronic apparatus 2. The housing 3 may be a cover which protects inner elements such as the display apparatus 1 and forms the exterior of the electronic apparatus 2. In addition, the display apparatus 1 may be connected to an electronic module of the electronic apparatus 2 and driven on the electronic apparatus 2. Hereinafter, the display apparatus 1 is mainly described.

As shown in FIG. 2, the display apparatus 1 may include a display area DA and a peripheral area PA, where a plurality of pixels PX is disposed in the display area DA, and the peripheral area PA is outside the display area DA. Specifically, the peripheral area PA may surround the display area DA entirely.

Each pixel PX of the display apparatus 1 is a region that may emit light of a preset color. The display apparatus 1 may display images by light from the pixels PX. In an embodiment, each pixel PX may emit red light, green light, or blue light. As shown in FIG. 2, the display area DA may have a polygonal shape including a quadrangular shape. In an embodiment, the display area DA may have a quadrangular shape, e.g., rectangular shape in which a horizontal length thereof is less than a vertical length thereof, a quadrangular shape, e.g., rectangular shape in which a horizontal length thereof is greater than a vertical length thereof, or a square shape. In an alternative embodiment, the display area DA may have various shapes such as an elliptical shape or a circular shape.

The peripheral area PA may be a non-display area in which the pixels PX are not disposed. A driver or the like which provides electrical signals or power to the pixels PX may be disposed in the peripheral area PA. A plurality of pads (not shown) may be disposed in the peripheral area PA, where the pads are a region to which electronic elements or a printed circuit board may be electrically connected. The pads may be spaced apart from each other in the peripheral area PA and electrically connected to a printed circuit board or an integrated circuit element.

Hereinafter, although an organic light-emitting display apparatus is described in an embodiment of the display apparatus 1, the display apparatus according to the disclosure is not limited thereto. In another embodiment, the display apparatus 1 may be an inorganic light-emitting display apparatus or a quantum-dot light-emitting display apparatus. In an embodiment, an emission layer of a display element of the display apparatus 1 may include an organic material or an inorganic material. In addition, the display apparatus 1 may include an emission layer and a quantum-dot layer disposed on a path of light emitted from the emission layer.

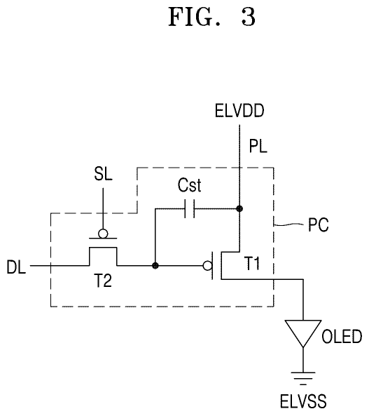

FIG. 3 is an equivalent circuit diagram of a pixel circuit PC included in the display apparatus 1 of FIG. 2. The pixel circuit PC may be electrically connected to a display element, and one display element may correspond to one pixel PX. That is, the display element may emit red light, green light, or blue light. FIG. 3 shows an organic light-emitting element (e.g., organic light-emitting diode) OLED as the display element.

The pixel circuit PC may include a first transistor T1, a second transistor T2, and a storage capacitor Cst. The second transistor T2 is a switching thin-film transistor, may be connected to a scan line SL and a data line DL and may be turned on according to a switching signal and transfer a data signal to the first transistor T1, the data signal being input from the data line DL, and the switching signal being input from the scan line SL. The storage capacitor Cst includes one end electrically connected to the second transistor T2, and an opposite end electrically connected to a driving voltage line PL. The storage capacitor Cst may store a voltage corresponding to a difference between a voltage transferred from the second transistor T2 and a driving power voltage ELVDD supplied to the driving voltage line PL.

The first transistor T1 is a driving transistor, may be connected to the driving voltage line PL and the storage capacitor Cst, and may control the magnitude of a driving current according to the voltage stored in the storage capacitor Cst, the driving current flowing from the driving voltage line PL to the organic light-emitting element OLED. The organic light-emitting element OLED may emit light having a preset brightness corresponding to the driving current. An opposite electrode of the organic light-emitting element OLED may receive an electrode power voltage ELVSS.

Although it is described with reference to FIG. 3 that the pixel circuit PC includes two transistors and one storage capacitor, the disclosure is not limited thereto. In an embodiment, the number of transistors and the number of storage capacitors may be variously changed according to the design of the pixel circuit PC.

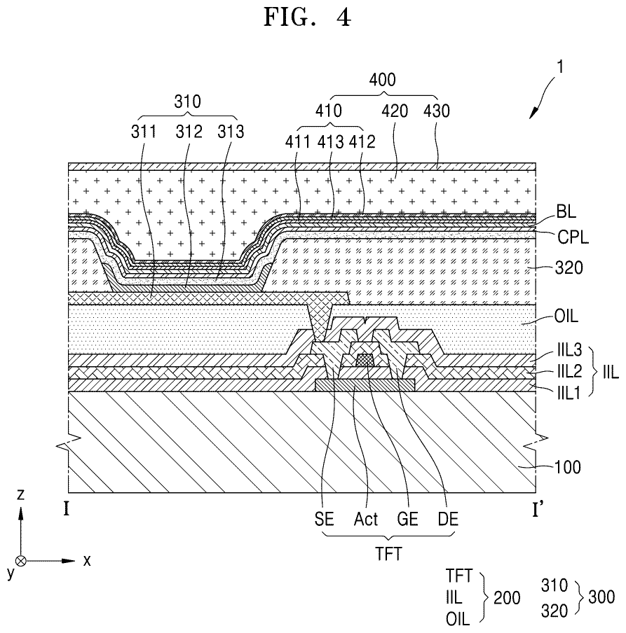

FIG. 4 is a schematic cross-sectional view of the display apparatus 1 of FIG. 2, taken along line I-I′ of FIG. 2. As recognized by those of ordinary skill in the art, the display apparatus 1 may further include other elements in addition to the elements shown in FIG. 4.

As shown in FIG. 4, the display apparatus 1 may include a substrate 100, a pixel circuit layer 200, a display element layer 300, a capping layer CPL, a buffer layer BL, and an encapsulation layer 400. Because the display apparatus 1 includes the substrate 100, it may be understood that the substrate 100 includes the display area DA and the peripheral area PA. Hereinafter, for convenience, description is made on the assumption that the substrate 100 includes the display area DA and the peripheral area PA.

The substrate 100 may include glass, metal, or polymer resin. The substrate 100 needs to be flexible or bendable. In this case, the substrate 100 may include polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure including two layers each including the polymer resin, and a barrier layer including an inorganic material (such as silicon oxide (SiO_{X}), silicon nitride (SiN_{X}), silicon oxynitride (SiO_{X}N_{Y}), or the like) therebetween. However, various modifications may be made.

The pixel circuit layer 200 may be disposed on the substrate 100. The pixel circuit layer 200 may include a transistor TFT, an inorganic insulating layer IIL, and an organic insulating layer OIL. The transistor TFT may include a semiconductor layer Act, a gate electrode GE, a source electrode SE, and a drain electrode DE. The inorganic insulating layer IIL may include a gate insulating layer IIL1, a first inter-insulating layer IIL2, and a second inter-insulating layer IIL3. For convenience of illustration, one transistor TFT is shown in FIG. 4, and the transistor TFT may correspond to the first transistor T1 (refer to FIG. 3).

The semiconductor layer Act may be disposed on the substrate 100. The semiconductor layer Act may include polycrystalline silicon. In an alternative embodiment, the semiconductor layer Act may include amorphous silicon, an oxide semiconductor, or an organic semiconductor. In an embodiment, the semiconductor layer Act may include a channel region, a drain region, and a source region, the drain region and the source region being on two opposite sides of the channel region.

The gate insulating layer IIL1 may be disposed on the semiconductor layer Act and the substrate 100. The gate insulating layer IIL1 may include an inorganic insulating material such as silicon oxide (SiO_{X}), silicon nitride (SiN_{X}), or silicon oxynitride (SiO_{X}N_{Y}). In an embodiment, the gate insulating layer IIL1 may have a single-layered structure or a multi-layered structure including the above materials. The insulating layer including the inorganic insulating material may be formed through chemical vapor deposition. This is also applicable to embodiments below and modifications thereof.

Although it is shown in FIG. 4 that the gate insulating layer IIL1 has a shape corresponding to the entirety of the surface of the substrate 100 and has a structure in which contact holes are formed in a preset portion, the disclosure is not limited thereto. In an embodiment, the gate insulating layer IIL1 may be patterned in the same shape as that of the shape of the gate electrode GE.

The gate electrode GE may be disposed on the gate insulating layer IIL1. That is, because the gate insulating layer IIL1 is disposed between the semiconductor layer Act and the gate electrode GE, insulation between the semiconductor layer Act and the gate electrode GE may be secured. The gate electrode GE may overlap the channel region of the semiconductor layer Act. The gate electrode GE may include a low-resistance metal material. In an embodiment, the gate electrode GE may include a conductive material including molybdenum (Mo), aluminum (Al), copper (Cu), and titanium (Ti) and have a single-layered structure or a multi-layered structure including the above conductive materials.

The first inter-insulating layer IIL2 may be disposed on the gate electrode GE and the gate insulating layer IIL1. The first inter-insulating layer IIL2 may include an inorganic insulating material such as silicon oxide (SiO_{X}), silicon nitride (SiN_{X}), or silicon oxynitride (SiO_{X}N_{Y}). In an embodiment, the first inter-insulating layer IIL2 may have a single-layered structure or a multi-layered structure including the above materials.

The source electrode SE and the drain electrode DE may be disposed on the first inter-insulating layer IIL2. Each of the source electrode SE and the drain electrode DE may be connected to the semiconductor layer Act through a contact hole defined in the first inter-insulating layer IIL2. At least one of the source electrode SE and the drain electrode DE may include a conductive material including molybdenum (Mo), aluminum (Al), copper (Cu), and titanium (Ti) and include a single-layered structure or a multi-layered structure including the above conductive materials. In an embodiment, at least one of the source electrode SE and the drain electrode DE may have a multi-layered structure of Ti/Al/Ti.

However, the disclosure is not limited thereto. In an embodiment, the transistor TFT may have only one of the source electrode SE and the drain electrode DE, or have neither of them. In an embodiment, one transistor TFT does not have a drain electrode DE, another transistor TFT connected to the transistor TFT does not have a source electrode SE, and semiconductor layers Act of the two transistors may be connected to each other. This connection structure may bring about the same effect as when one transistor TFT has a source electrode SE and another transistor TFT has a drain electrode DE, and the source electrode SE of one transistor TFT is connected to the drain electrode DE of a remaining (the other) transistor TFT.

The second inter-insulating layer IIL3 may be disposed on the source electrode SE, the drain electrode DE, and the first inter-insulating layer IIL2. The second inter-insulating layer IIL3 may include an inorganic insulating material such as silicon oxide (SiO_{X}), silicon nitride (SiN_{X}), or silicon oxynitride (SiO_{X}N_{Y}). In an embodiment, the second inter-insulating layer IIL3 may have a single-layered structure or a multi-layered structure including the above materials.

The organic insulating layer OIL may be disposed on the second inter-insulating layer IIL3. The organic insulating layer OIL may generally planarize the upper portion of the pixel circuit layer 200. The organic insulating layer OIL may include an organic material, e.g., acryl, benzocyclobutene (“BCB”), or hexamethyldisiloxane (“HMDSO”). Although it is shown in FIG. 4 that the organic insulating layer OIL is a single layer, the organic insulating layer OIL may be a multi-layer. However, various modifications may be made.

The display element layer 300 may be disposed on the pixel circuit layer 200. The display element layer 300 may include a display element 310 and a pixel-defining layer 320. In other words, the display element 310 may be disposed over the substrate 100. The display element 310 may be electrically connected to the transistor TFT. The display element 310 may be an organic light-emitting element including, e.g., a pixel electrode 311, an opposite electrode 313, and an emission layer 312, where the emission layer 312 is disposed between the pixel electrode 311 and the opposite electrode 313. When the display element 310 is electrically connected to the transistor TFT, it may be understood that the pixel electrode 311 of the organic light-emitting element is electrically connected to the transistor TFT.

The pixel electrode 311 may be electrically connected to the transistor TFT by being in contact with one of the source electrode SE and the drain electrode DE through a contact hole defined in the second inter-insulating layer IIL3 and the organic insulating layer OIL. The pixel electrode 311 may include a conductive oxide such as indium tin oxide (“ITO”), indium zinc oxide (“IZO”), zinc oxide (ZnO), indium oxide (In₂O₃), indium gallium oxide (“IGO”), or aluminum zinc oxide (“AZO”). In another embodiment, the pixel electrode 311 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or any combinations thereof. In another embodiment, the pixel electrode 311 may further include a layer on/under the reflective layer, the layer including ITO, IZO, ZnO, or In₂O₃.

The pixel-defining layer 320 may cover the edges of the pixel electrode 311. The pixel-defining layer 320 may define a pixel opening, and the pixel opening may overlap the pixel electrode 311. In an embodiment, the pixel opening may expose the central portion of the pixel electrode 311, and at least a portion of the emission layer 312 of the display element 310 may be disposed in the pixel opening. An emission area of light emitted from the display element 310 may be defined by the pixel opening.

In addition, in a case shown in FIG. 4, the pixel-defining layer 320 may increase a distance between the edge of the pixel electrode 311 and the opposite electrode 313 over the pixel electrode 311. Accordingly, arcs or the like may be prevented from occurring at the edges of the pixel electrode 311. The pixel-defining layer 320 may include an organic insulating material such as polyimide or HMDSO. In an embodiment, the pixel-defining layer 320 may include a light-blocking material.

The opposite electrode 313 may be disposed over the pixel electrode 311. The opposite electrode 313 may be integrally provided over the entirety of the surface of the display apparatus 1, and accordingly, commonly provided over the plurality of display elements 310. That is, the opposite electrode 313 may be integrally provided over the plurality of display elements 310. Accordingly, the opposite electrode 313 may correspond to a plurality of pixel electrodes 311. The opposite electrode 313 may include a light-transmissive conductive layer including ITO, In₂O₃, or IZO, and include a semi-transmissive layer including metal such as aluminum (Al) or silver (Ag). In an embodiment, the opposite electrode 313 may be a semi-transmissive layer including magnesium (Mg) and silver (Ag).

The emission layer 312 that may emit light may be disposed between the pixel electrode 311 and the opposite electrode 313. The emission layer 312 may emit red, green, or blue light. The emission layer 312 may include a polymer organic material or a low-molecular weight organic material that may emit light having a preset color (red, green, or blue). In an embodiment, the emission layer 312 may include a polymer material such as a polyphenylene vinylene (“PPV”)-based material and a polyfluorene-based material. The emission layer 312 may be formed by screen printing, inkjet printing, laser induced thermal imaging (“LITI”), or the like. However, the disclosure is not limited thereto.

In an embodiment, a functional layer (not shown) may be disposed under and on the emission layer 312. The functional layer may include a hole injection layer (“HIL”), a hole transport layer (“HTL”), an electron transport layer (“ETL”), and/or an electron injection layer (“EIL”). The functional layer may be integrally provided over the plurality of pixel electrodes 311, or be patterned to correspond to each of the plurality of pixel electrodes 311.

The capping layer CPL may be disposed on the opposite electrode 313. In other words, the capping layer CPL may be disposed between the display element 310 and the encapsulation layer 400. The capping layer CPL may cover and protect the upper portion of the opposite electrode 313. In addition, the capping layer CPL may improve a light extraction efficiency of the display element 310 through constructive interferences or the like. In other words, a light extraction efficiency of the display element 310 may be improved by the capping layer CPL.

The capping layer CPL may be a layer with a relatively high refractive index. The capping layer CPL may have a refractive index greater than a refractive index of the buffer layer BL described below. Specifically, the capping layer CPL may have a refractive index of about 1.60 to about 2.30. In an embodiment, the capping layer CPL may have a refractive index of about 2.05. The capping layer CPL may have a thickness of about 500 angstroms (Å) to about 1,500 Å. In an embodiment, the capping layer CPL may have a thickness of about 900 Å. The capping layer CPL may include an inorganic insulating material or an organic insulating material. Although it is shown in FIG. 4 that the capping layer CPL includes one layer, the disclosure is not limited thereto. In another embodiment, the capping layer CPL may have a structure in which a plurality of layers is stacked. That is, the capping layer CPL may have a multi-layered structure including the above materials.

The buffer layer BL may be disposed on the capping layer CPL. In other words, the buffer layer BL may be disposed between the capping layer CPL and the encapsulation layer 400. That is, the buffer layer BL may block plasma or the like used in a process of forming the encapsulation layer 400 such that the plasma or the like does not penetrate the display element 310 and cause damage to the emission layer 312, the opposite electrode 313, or the like.

The buffer layer BL may be a layer with a relatively low refractive index. The buffer layer BL may have a refractive index less than a refractive index of the capping layer CPL. In addition, the buffer layer BL may have a refractive index less than a refractive index of a first-first inorganic encapsulation layer 411. Specifically, the buffer layer BL may have a refractive index of about 1.20 to about 1.62. In an embodiment, the buffer layer BL may have a refractive index of about 1.39. The buffer layer BL may have a thickness of about 200 Å to about 1,400 Å. In an embodiment, the buffer layer BL may have a thickness of about 400 Å. The buffer layer BL may include an inorganic material such as lithium fluoride (LiF), magnesium fluoride (MgF₂), or calcium fluoride (CaF₂). In an embodiment, the buffer layer BL may include lithium fluoride (LiF).

Because the display element 310 may be easily damaged by external moisture, oxygen, or the like, the encapsulation layer 400 may protect the display element 310 by covering the display element 310. That is, the encapsulation layer 400 may be disposed on the display element 310. In an embodiment, the encapsulation layer 400 may be disposed on the buffer layer BL. As shown in FIG. 4, the encapsulation layer 400 may include a first inorganic encapsulation layer 410, an organic encapsulation layer 420, and a second inorganic encapsulation layer 430. In an embodiment, the encapsulation layer 400 may be disposed on the buffer layer BL, where the encapsulation layer 400 includes the first inorganic encapsulation layer 410, the second inorganic encapsulation layer 430, and the organic encapsulation layer 420 therebetween.

The first inorganic encapsulation layer 410 may cover the opposite electrode 313 and may include at least one of silicon oxide (SiO_{X}), silicon nitride (SiN_{X}), and silicon oxynitride (SiO_{X}N_{Y}). Because the first inorganic encapsulation layer 410 is formed along a structure thereunder, the upper surface of the first inorganic encapsulation layer 410 may not be flat as shown in FIG. 4. The first inorganic encapsulation layer 410 may include a plurality of sub-layers, and the structure of the first inorganic encapsulation layer 410 is described below in detail.

The organic encapsulation layer 420 may cover the first inorganic encapsulation layer 410. The organic encapsulation layer 420 may be disposed on the first inorganic encapsulation layer 410. In other words, the organic encapsulation layer 420 may be disposed between the first inorganic encapsulation layer 410 and the second inorganic encapsulation layer 430. Unlike the first inorganic encapsulation layer 410, the upper surface of the organic encapsulation layer 420 may be approximately planarized. The organic encapsulation layer 420 may include at least one material selected from among polyethylene terephthalate, polyethylene naphthalate, polycarbonate, polyimide, polyethylene sulfonate, polyoxymethylene, polyarylate, and hexamethyldisiloxane.

The second inorganic encapsulation layer 430 may cover the organic encapsulation layer 420. The second inorganic encapsulation layer 430 may be disposed on the organic encapsulation layer 420 and be in direct contact with the organic encapsulation layer 420. The second inorganic encapsulation layer 430 may include at least one of silicon nitride (SiN_{X}), and silicon oxynitride (SiO_{X}N_{Y}).

Because the encapsulation layer 400 includes the first inorganic encapsulation layer 410, the organic encapsulation layer 420, and the second inorganic encapsulation layer 430, even when cracks occur inside the encapsulation layer 400, the cracks may not be connected between the first inorganic encapsulation layer 410 and the organic encapsulation layer 420 or between the organic encapsulation layer 420 and the second inorganic encapsulation layer 430 through the above multi-layered structure. With this configuration, forming of a path through which external moisture or oxygen penetrates the inside of the display apparatus 1 may be prevented or reduced.

As described above, the first inorganic encapsulation layer 410 may include a plurality of sub-layers. That is, the first inorganic encapsulation layer 410 may have a structure in which the plurality of sub-layers is stacked. Refractive indexes of the plurality of sub-layers included in the first inorganic encapsulation layer 410 may be different from each other.

Generally, at least a portion of light emitted from the display element 310 may be reflected or refracted at interfaces between layers disposed on the display element 310. Reflection and/or refraction of light emitted from the display element 310 may be controlled by adjusting the refractive indexes and thicknesses of the layers disposed on the display element 310. That is, a light extraction efficiency and a viewing angle characteristic of the display element 310 may be controlled by adjusting the refractive indexes and thicknesses of the layers disposed on the display element 310. Accordingly, the layers disposed on the display element 310 may serve as an optical layer. However, in the case where the thickness of the layer disposed on the display element 310 may excessively thick, such as 6,000 Å or more, or excessively thin, such as 1,000 Å or less, such a layer may not serve as an optical layer.

In the case where the first inorganic encapsulation layer 410 has a structure in which a plurality of sub-layers having different refractive indexes is stacked, at least a portion of light emitted from the display element 310 may be reflected or refracted at an interface between the plurality of sub-layers of the first inorganic encapsulation layer 410. Reflection and/or refraction of light emitted from the display element 310 may be controlled by adjusting the refractive indexes and thicknesses of the plurality of sub-layers of the first inorganic encapsulation layer 410. That is, a light extraction efficiency and a viewing angle characteristic of the display element 310 may be controlled by adjusting the refractive indexes and thicknesses of the plurality of sub-layers of the first inorganic encapsulation layer 410. Accordingly, the first inorganic encapsulation layer 410 may serve as an optical layer.

Specifically, the first inorganic encapsulation layer 410 may include the first-first inorganic encapsulation layer 411 and a first-second inorganic encapsulation layer 412 disposed on the first-first inorganic encapsulation layer 411. The first inorganic encapsulation layer 410 may further include a first-third inorganic encapsulation layer 413, and the first-third inorganic encapsulation layer 413 may be disposed between the first-first inorganic encapsulation layer 411 and the first-second inorganic encapsulation layer 412. That is, the first-third inorganic encapsulation layer 413 may be disposed on the first-first inorganic encapsulation layer 411, and the first-second inorganic encapsulation layer 412 may be disposed on the first-third inorganic encapsulation layer 413. The first-third inorganic encapsulation layer 413 may be in direct contact with the first-first inorganic encapsulation layer 411, and the first-second inorganic encapsulation layer 412 may be in direct contact with the first-third inorganic encapsulation layer 413. In other words, the first-third inorganic encapsulation layer 413 may be directly disposed on the first-first inorganic encapsulation layer 411, and the first-second inorganic encapsulation layer 412 may be directly disposed on the first-third inorganic encapsulation layer 413.

The plurality of sub-layers of the first inorganic encapsulation layer 410 may have different refractive indexes. The first-first inorganic encapsulation layer 411 may be a high refractive index layer having a relatively high refractive index, and the first-second inorganic encapsulation layer 412 may be a low refractive index layer having a relatively low refractive index. That is, a refractive index of the first-second inorganic encapsulation layer 412 may be less than a refractive index of the first-first inorganic encapsulation layer 411. A refractive index of the first-third inorganic encapsulation layer 413 may be less than a refractive index of the first-first inorganic encapsulation layer 411 and greater than a refractive index of the first-second inorganic encapsulation layer 412. That is, the first-third inorganic encapsulation layer 413 may be an intermediate refractive index layer.

Specifically, the first-first inorganic encapsulation layer 411 may have a refractive index of about 1.85 to about 2.00, and the first-second inorganic encapsulation layer 412 may have a refractive index of about 1.52 to about 1.70. The first-third inorganic encapsulation layer may have a refractive index of greater than 1.75 and less than 1.80. In an embodiment, a refractive index of the first-first inorganic encapsulation layer 411 may be about 1.89, and a refractive index of the first-second inorganic encapsulation layer 412 may be about 1.62. A refractive index of the first-third inorganic encapsulation layer 413 may be about 1.77.

Each of the plurality of sub-layers included in the first inorganic encapsulation layer 410 may include an inorganic insulating material including silicon (Si) such as silicon oxide (SiO_{X}), silicon nitride (SiN_{X}), or silicon oxynitride (SiO_{X}N_{Y}). Refractive indexes of the plurality of sub-layers may vary depending on the content of nitrogen (N) and oxygen (O) contained in each of the plurality of sub-layers.

In an embodiment, the first-first inorganic encapsulation layer 411 may include silicon nitride (SiN_{X}). Each of the first-second inorganic encapsulation layer 412 and the first-third inorganic encapsulation layer 413 may include silicon oxynitride (SiO_{X}N_{Y}). The content of nitrogen (N) contained in the first-third inorganic encapsulation layer 413 may be greater than the content of nitrogen (N) contained in the first-second inorganic encapsulation layer 412, and the content of oxygen (O) contained in the first-third inorganic encapsulation layer 413 may be less than the content of oxygen (O) contained in the first-second inorganic encapsulation layer 412.

In an embodiment, the first-first inorganic encapsulation layer 411 may include about 58 wt % of silicon (Si) and about 42 wt % of nitrogen (N) based on the total weight of the first-first inorganic encapsulation layer 411. That is, the first-first inorganic encapsulation layer 411 may not include oxygen (O). The first-second inorganic encapsulation layer 412 may include about 47 wt % of silicon (Si), about 22 wt % of nitrogen (N), and about 31 wt % of oxygen (O) based on the total weight of the first-second inorganic encapsulation layer 412. The first-third inorganic encapsulation layer 413 may include about 52 wt % of silicon (Si), about 34 wt % of nitrogen (N), and about 14 wt % of oxygen (O) based on the total weight of the first-third inorganic encapsulation layer 413. The content of silicon (Si) and nitrogen (N) contained in the plurality of sub-layers may be determined using X-ray photoelectron spectroscopy (“XPS”). Because determining the content of silicon (Si) and nitrogen (N) using XPS is common in the manufacturing of display apparatuses, detailed description thereof is omitted.

Generally, in the case where one layer includes an inorganic insulating material including or consisting of silicon (Si), as the content of nitrogen (N) contained in the layer increases, the refractive index of the layer increases. In addition, as the content of oxygen (O) contained in the layer reduces, the reliability of the layer increases.

In the case where the first inorganic encapsulation layer 410 includes the first-third inorganic encapsulation layer 413, the first-third inorganic encapsulation layer 413 is in direct contact with the first-first inorganic encapsulation layer 411, which is a relatively high refractive layer. Because a difference between the refractive index of the first-first inorganic encapsulation layer 411 and the refractive index of the first-third inorganic encapsulation layer 413 is not large, reflection and/or refraction of light occurring at an interface formed by the first-first inorganic encapsulation layer 411 is not large. However, in the case where the first inorganic encapsulation layer 410 forms the first-third inorganic encapsulation layer 413, the first-first inorganic encapsulation layer 411 and the first-third inorganic encapsulation layer 413 form an interface, and the first-third inorganic encapsulation layer 413 and the first-second inorganic encapsulation layer 412 form an interface. Accordingly, reflection and/or refraction of light emitted from the display element 310 may occur not only at an interface between the first-first inorganic encapsulation layer 411 and the first-third inorganic encapsulation layer 413 but also at an interface between the first-third inorganic encapsulation layer 413 and the first-second inorganic encapsulation layer 412.

In contrast, in the case where the first-second inorganic encapsulation layer 412 is in direct contact with the first-first inorganic encapsulation layer 411, that is, in the case where the first inorganic encapsulation layer 410 does not include the first-third inorganic encapsulation layer 413, only the first-first inorganic encapsulation layer 411 and the first-second inorganic encapsulation layer 412 form an interface. Accordingly, reflection and/or refraction of light emitted from the display element 310 may occur at only an interface between the first-first inorganic encapsulation layer 411 and the first-second inorganic encapsulation layer 412. Accordingly, in the illustrated embodiment, because reflection and/or refraction of light may occur at more interfaces, control of the light extraction efficiency and viewing angle characteristics of the display element 310 may be facilitated.

In addition, in the case where the first inorganic encapsulation layer 410 includes the first-third inorganic encapsulation layer 413, the first-second inorganic encapsulation layer 412 having a relatively thin thickness with reference to the first inorganic encapsulation layer 410 having a predetermined thickness is included in the first inorganic encapsulation layer 410. That is, assuming that a relative thickness of the first inorganic encapsulation layer 410 is 1, a relative thickness of the first-first inorganic encapsulation layer 411 may be about 0.1, a relative thickness of the first-second inorganic encapsulation layer 412 may be about 0.6, and a relative thickness of the first-third inorganic encapsulation layer 413 may be about 0.3.

In contrast, in the case where the first-second inorganic encapsulation layer 412 is in direct contact with the first-first inorganic encapsulation layer 411, a relative thickness of the first-first inorganic encapsulation layer 411 with reference to the first inorganic encapsulation layer 410 having the same predetermined thickness may be about 0.1, and a relative thickness of the first-second inorganic encapsulation layer 412 may be about 0.9. Accordingly, in the illustrated embodiment, because the thickness of the first-second inorganic encapsulation layer 412 having a relatively high oxygen (O) content may be thin, the reliability of the first inorganic encapsulation layer 410 may increase. That is, the reliability of the display apparatus 1 may increase.

In an embodiment, the first-first inorganic encapsulation layer 411 may have a thickness of about 1,150 Å to about 1,550 Å. The first-second inorganic encapsulation layer 412 may have a thickness of about 5,200 Å to about 6,200 Å, and the first-third inorganic encapsulation layer 413 may have a thickness of about 2,500 Å to about 3,500 Å. In an embodiment, the first-first inorganic encapsulation layer 411 may have a thickness of about 1,350 Å. The first-second inorganic encapsulation layer 412 may have a thickness of about 5,700 Å, and the first-third inorganic encapsulation layer 413 may have a thickness of about 3,000 Å.

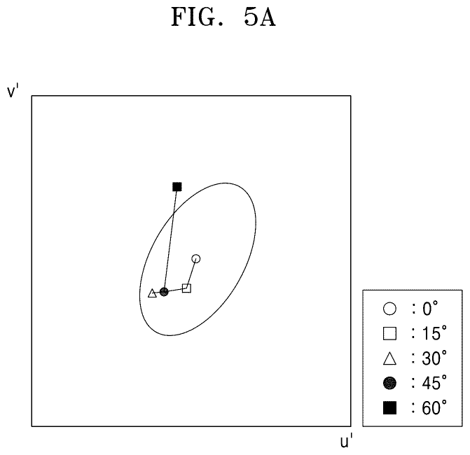

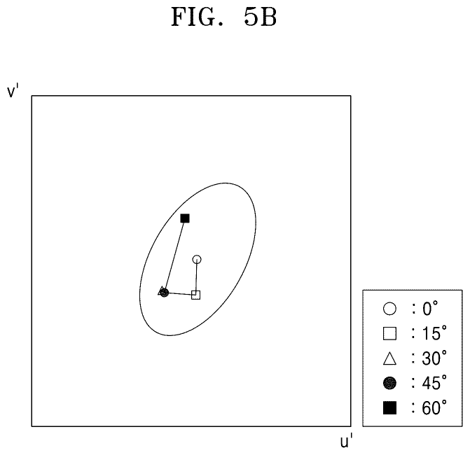

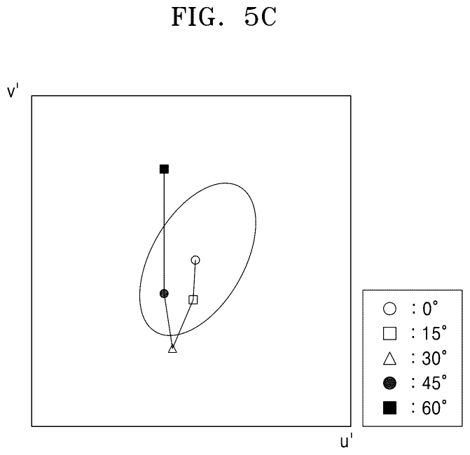

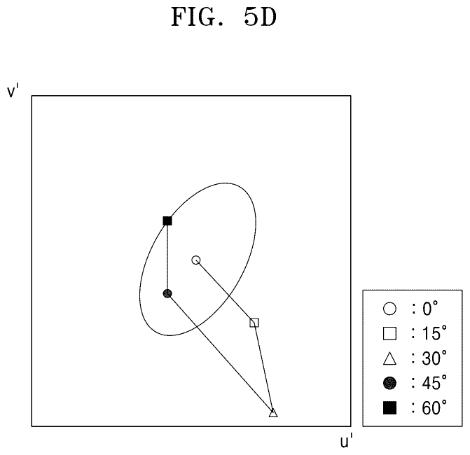

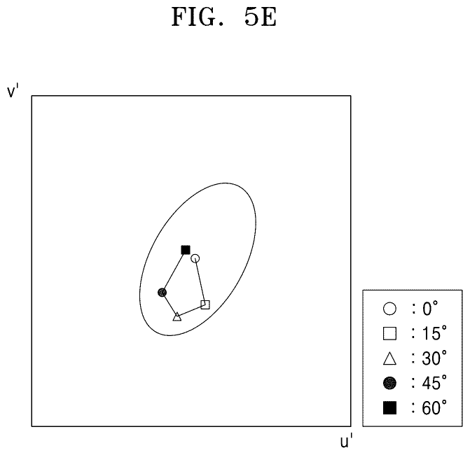

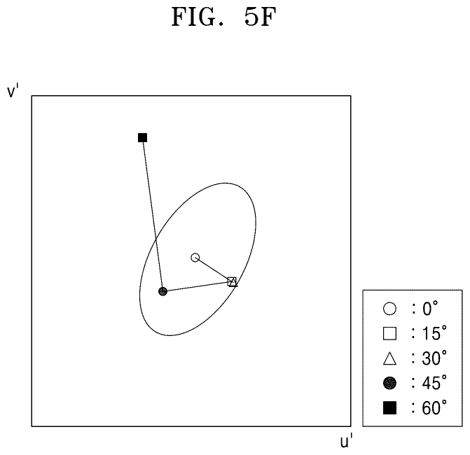

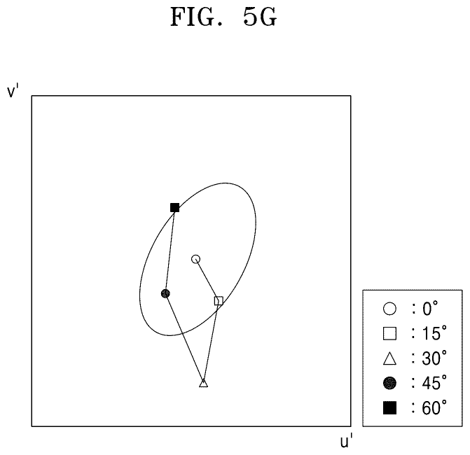

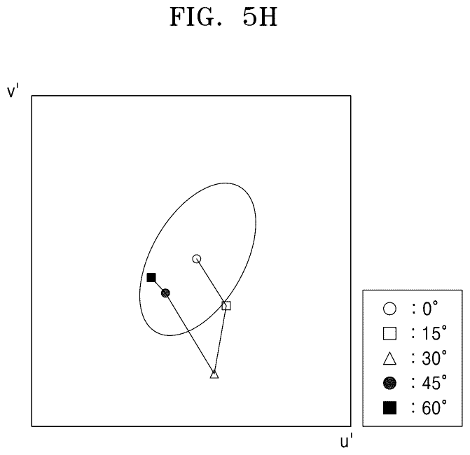

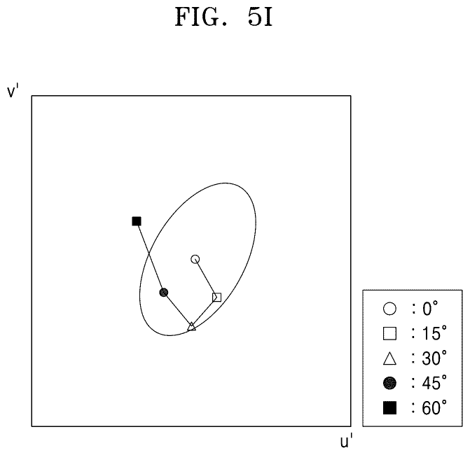

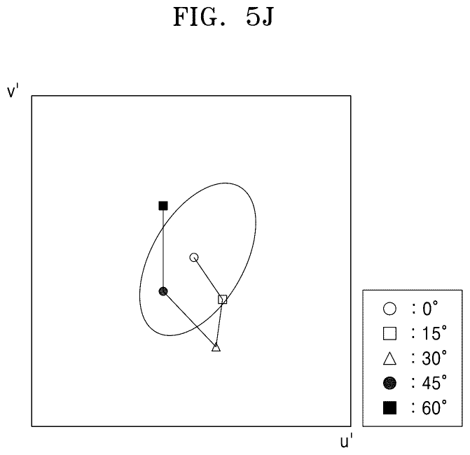

FIGS. 5A to 5J are views to explain an influence of thicknesses of sub-layers of the first inorganic encapsulation layer 410 on color coordinates according to a viewing angle. FIGS. 5A to 5J are relative color coordinates according to viewing angles. Specifically, FIGS. 5A to 5J show relative positions of color coordinates according to viewing angles based on a CIE 1976 color coordinate system. In an embodiment, in FIGS. 5A to 5J, a horizontal position may be related to Δu′, and a vertical position may be related to Δv′.

Because FIGS. 5A to 5J are diagrams to explain a difference in color coordinate changes according to viewing angles, predetermined values of the color coordinates are omitted, and in FIGS. 5A to 5J, an ellipse representing the optical characteristics desired for the display apparatus 1 is also shown for the convenience of description. That is, in FIGS. 5A to 5J, color coordinates should be disposed inside the ellipse to correspond to a case (SPEC IN) where the display apparatus 1 satisfies desired optical characteristics.

In FIGS. 5A to 5J, a circle of which the inside is not colored represents color coordinates when a viewing angle is 0°. In FIGS. 5A to 5J, a quadrangle of which the inside is not colored denotes color coordinates when a viewing angle is 15°, a triangle of which the inside is not colored denotes color coordinates when a viewing angle is 30°, a circle of which the inside is colored denotes color coordinates when a viewing angle is 45°, and a quadrangle of which the inside is colored denotes color coordinates when a viewing angle is 60°. In FIGS. 5A to 5J, the closer the color coordinates when a viewing angle is not about 0° are to the color coordinates when a viewing angle is about 0°, the less the color coordinates change due to changes in a viewing angle. That is, the closer the color coordinates when a viewing angle is not about 0° are to the color coordinates when a viewing angle is about 0°, color shift on a lateral side of light emitted from the display apparatus 1, e.g., white angular dependency (“WAD”), is small.

FIG. 5A shows color coordinates according to viewing angles in Comparative Example 1, and Comparative Example 1 has the first-first inorganic encapsulation layer 411 having a thickness of about 1,150 Å, the first-second inorganic encapsulation layer 412 having a thickness of about 5,700 Å, and the first-third inorganic encapsulation layer 413 having a thickness of about 3,000 Å. FIG. 5B shows color coordinates according to viewing angles in Comparative Example 2, and Comparative Example 2 has the first-first inorganic encapsulation layer 411 having a thickness of about 1,250 Å, the first-second inorganic encapsulation layer 412 having a thickness of about 5,700 Å, and the first-third inorganic encapsulation layer 413 having a thickness of about 3,000 Å. FIG. 5C shows color coordinates according to viewing angles in Comparative Example 3, and Comparative Example 3 has the first-first inorganic encapsulation layer 411 having a thickness of about 1,350 Å, the first-second inorganic encapsulation layer 412 having a thickness of about 7,700 Å, and the first-third inorganic encapsulation layer 413 having a thickness of about 1,000 Å. FIG. 5D shows color coordinates according to viewing angles in Comparative Example 4, and Comparative Example 4 has the first-first inorganic encapsulation layer 411 having a thickness of about 1,350 Å, the first-second inorganic encapsulation layer 412 having a thickness of about 6,700 Å, and the first-third inorganic encapsulation layer 413 having a thickness of about 2,000 Å.

FIG. 5E shows color coordinates according to viewing angles in Embodiment 1, and Embodiment 1 has the first-first inorganic encapsulation layer 411 having a thickness of about 1,350 Å, the first-second inorganic encapsulation layer 412 having a thickness of about 5,700 Å, and the first-third inorganic encapsulation layer 413 having a thickness of about 3,000 Å. FIG. 5F shows color coordinates according to viewing angles in Comparative Example 5, and Comparative Example 5 has the first-first inorganic encapsulation layer 411 having a thickness of about 1,350 Å, the first-second inorganic encapsulation layer 412 having a thickness of about 4,700 Å, and the first-third inorganic encapsulation layer 413 having a thickness of about 4,000 Å. FIG. 5G shows color coordinates according to viewing angles in Comparative Example 6, and Comparative Example 6 has the first-first inorganic encapsulation layer 411 having a thickness of about 1,350 Å, the first-second inorganic encapsulation layer 412 having a thickness of about 3,700 Å, and the first-third inorganic encapsulation layer 413 having a thickness of about 5,000 Å. FIG. 5H shows color coordinates according to viewing angles in Comparative Example 7, and Comparative Example 7 has the first-first inorganic encapsulation layer 411 having a thickness of about 1,350 Å, the first-second inorganic encapsulation layer 412 having a thickness of about 2,700 Å, and the first-third inorganic encapsulation layer 413 having a thickness of about 6,000 Å.

FIG. 5I shows color coordinates according to viewing angles in Comparative Example 8, and Comparative Example 8 has the first-first inorganic encapsulation layer 411 having a thickness of about 1,350 Å, the first-second inorganic encapsulation layer 412 having a thickness of about 1,700 Å, and the first-third inorganic encapsulation layer 413 having a thickness of about 7,000 Å. FIG. 5J shows color coordinates according to viewing angles in Comparative Example 9, and Comparative Example 9 has the first-first inorganic encapsulation layer 411 having a thickness of about 1,350 Å, the first-second inorganic encapsulation layer 412 having a thickness of about 700 Å, and the first-third inorganic encapsulation layer 413 having a thickness of about 8,000 Å.

Comparative Examples 1 to 9 and Embodiment 1 differ only in the thicknesses of the sub-layers of the first inorganic encapsulation layer 410, and remaining (the other) elements are the same or similar. Specifically, Comparative Examples 3 to 9 and Embodiment 1 differ only in the thicknesses of the first-first inorganic encapsulation layer 412 and the first-third inorganic encapsulation layer 413. Comparative Examples 1 and 2, and Embodiment 1 differ only in the thickness of the first-first inorganic encapsulation layer 411.

Referring to FIGS. 5C to 5J, in the case where the thickness of the first-second inorganic encapsulation layer 412 is about 5,200 Å to about 6,200 Å, and the thickness of the first-third inorganic encapsulation layer 413 is about 2,500 Å to about 3,500 Å, all of the color coordinates are disposed inside the ellipse. Specifically, in the case where Comparative Examples 3 to 9 in which the thickness of the first-second inorganic encapsulation layer 412 deviates from the range of about 5,200 Å to about 6,200 Å, and the thickness of the first-third inorganic encapsulation layer 413 deviates from the range of about 2,500 Å to about 3,500 Å, at least one of the color coordinates is disposed outside the ellipse. In the case of Embodiment 1 in which the thickness of the first-second inorganic encapsulation layer 412 is in the range of about 5,200 Å to about 6,200 Å, and the thickness of the first-third inorganic encapsulation layer 413 is in the range of about 2,500 Å to about 3,500 Å, all of the color coordinates are disposed inside the ellipse.

Accordingly, in the case where the thickness of the first-second inorganic encapsulation layer 412 is in the range of about 5,200 Å to about 6,200 Å, and the thickness of the first-third inorganic encapsulation layer 413 is in the range of about 2,500 Å to about 3,500 Å, the display apparatus 1 satisfies desired optical characteristics. In addition, in the case where the thickness of the first-second inorganic encapsulation layer 412 is in the range of about 5,200 Å to about 6,200 Å, and the thickness of the first-third inorganic encapsulation layer 413 is in the range of about 2,500 Å to about 3,500 Å, color coordinates when a viewing angle is not about 0° are disposed close to color coordinates when a viewing angle is about 0°. That is, compared to Comparative Examples 3 to 9, Embodiment 1 shows a smaller change in color coordinates according to a change in a viewing angle. In other words, color shift on a lateral side of light emitted from the display apparatus 1, e.g., WAD, is small. Accordingly, the display quality of the display apparatus 1 may be improved.

Referring to FIGS. 5A, 5B, and 5E, in the case where the thickness of the first-first inorganic encapsulation layer 411 is about 1,150 Å to about 1,550 Å, color coordinates when a viewing angle is not about 0° are disposed close to color coordinates when a viewing angle is about 0°. That is, compared to Comparative Examples 1 and 2, Embodiment 1 shows a smaller change in color coordinates according to a change in a viewing angle. In other words, color shift on a lateral side of light emitted from the display apparatus 1, e.g., WAD, is small. Accordingly, the display quality of the display apparatus 1 may be improved.

Although it is shown in FIG. 4 that the first-second inorganic encapsulation layer 412 is in direct contact with the organic encapsulation layer 420, the disclosure is not limited thereto. In an embodiment, the first inorganic encapsulation layer 410 may further include an auxiliary layer AL disposed on the first-second inorganic encapsulation layer 412.

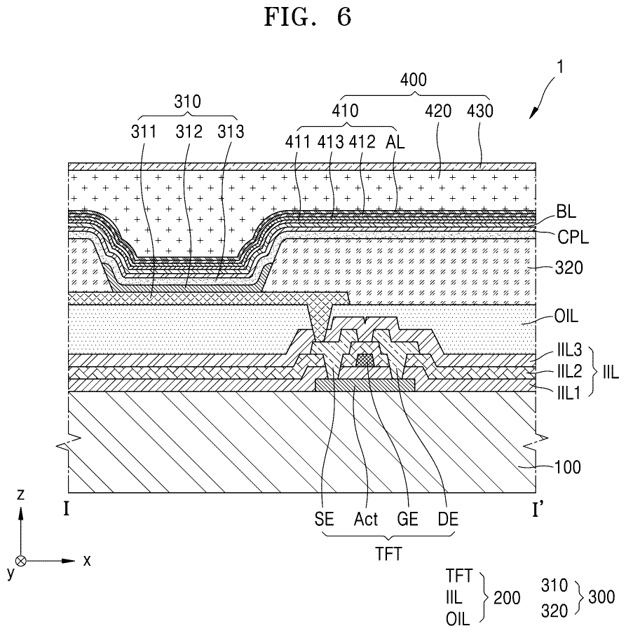

FIG. 6 is a schematic cross-sectional view of the display apparatus 1. Because the display apparatus 1 in an embodiment is similar to the display apparatus 1 described above with reference to FIGS. 1 to 4, differences from the display apparatus 1 described with reference to FIGS. 1 to 4 are mainly described below. In FIG. 6, the same reference numerals as those of FIGS. 1 to 4 denote the same members, and thus, repeated descriptions thereof are omitted.

The display apparatus 1 described above with reference to FIGS. 1 to 4 may include the first inorganic encapsulation layer 410, the organic inorganic encapsulation layer 420, and the second inorganic encapsulation layer 430, and the first inorganic encapsulation layer 410 may include the first-first inorganic encapsulation layer 411, the first-second inorganic encapsulation layer 412, and the first-third inorganic encapsulation layer 413. As shown in FIG. 6, even the display apparatus 1 in the illustrated embodiment may include the first inorganic encapsulation layer 410, the organic inorganic encapsulation layer 420, and the second inorganic encapsulation layer 430, and the first inorganic encapsulation layer 410 may include the first-first inorganic encapsulation layer 411, the first-second inorganic encapsulation layer 412, and the first-third inorganic encapsulation layer 413.

However, in the display apparatus 1 in the illustrated embodiment, the first inorganic encapsulation layer 410 may further include the auxiliary layer AL. The auxiliary layer AL may have a refractive index different from refractive indexes of the first-first inorganic encapsulation layer 411, the first-second inorganic encapsulation layer 412, and the first-third inorganic encapsulation layer 413. Specifically, the auxiliary layer AL may have a refractive index less than a refractive index of the first-second inorganic encapsulation layer 412. In an embodiment, in the case where a refractive index of the first-second inorganic encapsulation layer 412 is about 1.62, a refractive index of the auxiliary layer AL may be about 1.57. However, the disclosure is not limited thereto.

The auxiliary layer AL may include an inorganic insulating material including silicon nitride (SiN_{X}), silicon oxide (SiO_{X}), or silicon oxynitride (SiO_{X}N_{Y}). In an embodiment, the auxiliary layer AL may include silicon oxynitride (SiO_{X}N_{Y}). In an embodiment, the auxiliary layer AL may include about 46 wt % of silicon (Si), about 19 wt % of nitrogen (N), and about 35 wt % of oxygen (O) based on the total weight of the auxiliary layer AL.

The auxiliary layer AL may have a thickness of about 300 Å to about 1,000 Å. In an embodiment, the auxiliary layer AL may have a thickness of about 700 Å. However, the disclosure is not limited thereto. Even in the illustrated embodiment, the thickness of the first-second inorganic encapsulation layer 412 may be about 5,200 Å to about 6,200 Å, and the thickness of the first-third inorganic encapsulation layer 413 may be about 2,500 Å to about 3,500 Å. In addition, the thickness of the first-first inorganic encapsulation layer 411 may be about 1,150 Å to about 1,550 Å. Accordingly, even in the illustrated embodiment, the reliability of the display apparatus 1 may increase, and the display quality of the display apparatus 1 may improve.

In an embodiment having the above configuration, the display apparatus with improved reliability and improved display quality, and the electronic apparatus including the display apparatus may be implemented. However, the scope of the disclosure is not limited by this effect.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A display apparatus comprising:
a display element disposed over a substrate; and
an encapsulation layer disposed on the display element and including:
a first inorganic encapsulation layer including:
a first-first inorganic encapsulation layer including silicon nitride;
a first-second inorganic encapsulation layer disposed over the first-first inorganic encapsulation layer and having a refractive index less than a refractive index of the first-first inorganic encapsulation layer; and
a first-third inorganic encapsulation layer disposed between the first-first inorganic encapsulation layer and the first-second inorganic encapsulation layer and having a refractive index less than the refractive index of the first-first inorganic encapsulation layer and greater than the refractive index of the first-second inorganic encapsulation layer;
a second inorganic encapsulation layer; and
an organic encapsulation layer between the first inorganic encapsulation layer and the second inorganic encapsulation layer,
wherein the refractive index of the first-third inorganic encapsulation layer is greater than 1.75 and less than 1.80.

2. The display apparatus of claim 1, wherein the refractive index of the first-first inorganic encapsulation layer ranges from about 1.85 to about 2.00, and the refractive index of the first-second inorganic encapsulation layer ranges from about 1.52 to about 1.70.

3. The display apparatus of claim 1, wherein each of the first-second inorganic encapsulation layer and the first-third inorganic encapsulation layer includes silicon oxynitride, and oxygen content of the first-third inorganic encapsulation layer is less than oxygen content of the first-second inorganic encapsulation layer.

4. The display apparatus of claim 3, wherein nitrogen content of the first-third inorganic encapsulation layer is greater than nitrogen content of the first-second inorganic encapsulation layer.

5. The display apparatus of claim 1, wherein the first-second inorganic encapsulation layer has a thickness of about 5,200 angstroms to about 6,200 angstroms, and the first-third inorganic encapsulation layer has a thickness of about 2,500 angstroms to about 3,500 angstroms.

6. The display apparatus of claim 5, wherein the first-first inorganic encapsulation layer has a thickness of about 1,150 angstroms to about 1,550 angstroms.

7. The display apparatus of claim 1, wherein the first-third inorganic encapsulation layer is in direct contact with the first-first inorganic encapsulation layer, and the first-second inorganic encapsulation layer is in direct contact with the first-third inorganic encapsulation layer.

8. The display apparatus of claim 1, further comprising:
a capping layer disposed between the display element and the encapsulation layer; and
a buffer layer disposed between the capping layer and the encapsulation layer.

9. The display apparatus of claim 8, wherein the capping layer has a refractive index greater than a refractive index of the buffer layer, and the refractive index of the buffer layer is less than the refractive index of the first-first inorganic encapsulation layer.

10. The display apparatus of claim 9, wherein the refractive index of the capping layer ranges from about 1.60 to about 2.30, and the refractive index of the buffer layer ranges from about 1.20 to about 1.62.

11. An electronic apparatus comprising:
a display apparatus including:
a display element disposed over a substrate; and
an encapsulation layer disposed on the display element and including:
a first inorganic encapsulation layer, the first inorganic encapsulation layer including:
a first-first inorganic encapsulation layer including silicon nitride;
a first-second inorganic encapsulation layer disposed over the first-first inorganic encapsulation layer and having a refractive index less than a refractive index of the first-first inorganic encapsulation layer; and
a first-third inorganic encapsulation layer disposed between the first-first inorganic encapsulation layer and the first-second inorganic encapsulation layer and having a refractive index less than the refractive index of the first-first inorganic encapsulation layer and greater than the refractive index of the first-second inorganic encapsulation layer;
a second inorganic encapsulation layer; and
an organic encapsulation layer between the first inorganic encapsulation layer and the second inorganic encapsulation layer; and
a housing accommodating the display apparatus and constituting an exterior,
wherein the refractive index of the first-third inorganic encapsulation layer is greater than

1. 75 and less than 1.80.

12. The electronic apparatus of claim 11, wherein the refractive index of the first-first inorganic encapsulation layer ranges from about 1.85 to about 2.00, and the refractive index of the first-second inorganic encapsulation layer ranges from about 1.52 to about 1.70.

13. The electronic apparatus of claim 11, wherein each of the first-second inorganic encapsulation layer and the first-third inorganic encapsulation layer includes silicon oxynitride, and oxygen content of the first-third inorganic encapsulation layer is less than oxygen content of the first-second inorganic encapsulation layer.

14. The electronic apparatus of claim 13, wherein nitrogen content of the first-third inorganic encapsulation layer is greater than nitrogen content of the first-second inorganic encapsulation layer.

15. The electronic apparatus of claim 11, wherein the first-second inorganic encapsulation layer has a thickness of about 5,200 angstroms to about 6,200 angstroms, and the first-third inorganic encapsulation layer has a thickness of about 2,500 angstroms to about 3,500 angstroms.

16. The electronic apparatus of claim 15, wherein the first-first inorganic encapsulation layer has a thickness of about 1,150 angstroms to about 1,550 angstroms.

17. The electronic apparatus of claim 11, wherein the first-third inorganic encapsulation layer is in direct contact with the first-first inorganic encapsulation layer, and the first-second inorganic encapsulation layer is in direct contact with the first-third inorganic encapsulation layer.

18. The electronic apparatus of claim 11, further comprising:
a capping layer disposed between the display element and the encapsulation layer; and
a buffer layer disposed between the capping layer and the encapsulation layer.

19. The electronic apparatus of claim 18, wherein the capping layer has a refractive index greater than a refractive index of the buffer layer, and the refractive index of the buffer layer is less than the refractive index of the first-first inorganic encapsulation layer.

20. The electronic apparatus of claim 19, wherein the refractive index of the capping layer ranges from about 1.60 to about 2.30, and the refractive index of the buffer layer ranges from about 1.20 to about 1.62.
